(19) United States
(12) Patent Application Publication
(10) Pub. No.: US 2015/0123139 A1
(43) Pub. Date: May 7, 2015

(54) HIGH ELECTRON MOBILITY TRANSISTOR AND METHOD OF MANUFACTURING THE SAME

(71) Applicant: SAMSUNG ELECTRONICS CO., LTD., Suwon-Si (KR)

(72) Inventors: Jong-seob KIM, Seoul (KR); In-jun HWANG, Hwaseong-si (KR); Jai-kwang SHIN, Anyang-si (KR); Jae-joon OH, Seongnam-si (KR); Soo-gine CHONG, Seoul (KR); Sunk-yu HWANG, Seoul (KR)

(73) Assignee: SAMSUNG ELECTRONICS CO., LTD., Suwon-Si (KR)

(21) Appl. No.: 14/258,374

(22) Filed: Apr. 22, 2014

(30) Foreign Application Priority Data
Nov. 5, 2013 (KR) 10-2013-0133828

(51) Int. Cl. H01L 29/778; H01L 29/66

(52) U.S. Cl. CPC H01L 29/778; H01L 29/66462
USPC 257/76; 438/172

(57) ABSTRACT

Provided are a high electron mobility transistor and/or a method of manufacturing the same. The high electron mobility transistor includes a channel layer, a channel supply layer formed on the channel layer to generate a two-dimensional electron gas (2DEG), a depletion forming layer formed on the channel supply layer, a gate electrode formed on the depletion forming layer, and a barrier layer formed between the depletion forming layer and the gate electrode. Holes may be prevented from being injected into the depletion forming layer from the gate electrode, thereby reducing a gate forward current.

### RELATED APPLICATIONS

This application claims priority from Korean Patent Application No. 10-2013-0133828, filed on Nov. 5, 2013, in the Korean Intellectual Property Office, the disclosure of which is incorporated herein in its entirety by reference.

### BACKGROUND

1. Field

At least one example embodiment relates to a high electron mobility transistor and/or a method of manufacturing the same, and more particularly, to a high electron mobility transistor having a normally-off characteristic and/or a method of manufacturing the high electron mobility transistor.

2. Description of the Related Art

In power conversion systems, efficiency of the entire system depends on efficiency of a semiconductor switching device. A power metal oxide semiconductor field effect transistor (MOSFET) using silicon or an insulated gate bipolar transistor (IGBT) are typically used as the semiconductor switching device. However, it is difficult to increase efficiency of a silicon-based power device due to the limits of a property of silicon and the limits of a manufacturing process.

As an attempt for overcome such limits to the material of silicon, research into a high electron mobility transistor using a Group III-V compound semiconductor has been actively performed. The high electron mobility transistor typically includes semiconductor layers having different electrical polarization characteristics. A semiconductor layer having a relatively high polarizability in a high electron mobility transistor may generate a two-dimensional electron gas (2DEG) in another semiconductor layer coupled thereto by a heterojunction.

Since such a 2DEG is used as a channel, a high electron mobility transistor may have a high electron mobility. In addition, the high electron mobility transistor includes a compound semiconductor having a wide bang gap. Accordingly, a breakdown voltage of the high electron mobility transistor may be higher than that of a general transistor. The breakdown voltage of the high electron mobility transistor may be increased in proportion to a thickness of a compound semiconductor layer including a 2DEG, for example, a GaN layer. In addition, a normally-off function may be required for a normal operation of a power device.

### SUMMARY

At least one example embodiment relates to a high electron mobility transistor having a stable normally-off characteristic and a low resistance in an on state, according to at least one example embodiment.

Also provided is an example method of manufacturing a high electron mobility transistor having a stable normally-off characteristic.

At least one example embodiment will be set forth in part in the description which follows and, in part, will be apparent from the description, or may be learned by practice of at least one example embodiment.

According to at least one example embodiment, a high electron mobility transistor includes a channel layer; a channel supply layer formed on the channel layer; a source electrode and a drain electrode formed on the channel layer or on the channel supply layer; a gate structure formed on the channel supply layer between the source electrode and the drain electrode, wherein the gate structure comprises a depletion forming layer (alternatively referred to as a depletion forming unit) formed on the channel supply layer, a barrier layer formed on the depletion forming layer, and a gate electrode formed on the barrier layer.

The example barrier layer may be formed of a material having band gap energy or conduction band offset which is larger than the band gap energy or conduction band offset of a material of the depletion forming layer.

The barrier layer may be formed of a material having a chemical formula of AlₓGa₁₋ₓN (0≦x≦1).

The barrier layer may be of AlN.

The barrier layer may be formed of an oxide.

The barrier layer may be formed of SiN or Al₂O₃.

The barrier layer may be formed to have a thickness of equal to or less than 100 nm.

The depletion forming layer may be formed of a Group III-V nitride semiconductor material.

The depletion forming layer may be formed to comprise at least one of GaN, AlGaN, InN, AlInN, InGaN, and AlInGaN.

The depletion forming layer may be formed of a p-type semiconductor material.

The depletion forming layer may have a thickness of 30 to 250 nm.

The source electrode and the drain electrode may be formed on the channel supply layer.

The source electrode and the drain electrode may be formed on a surface of the channel layer.

The source electrode and the drain electrode may be formed to extend into the channel layer.

The high electron mobility transistor may further include a bridge formed between the source electrode and the depletion supply unit or between the drain electrode and the depletion supply unit.

The bridge may be formed of a Group III-V nitride semiconductor.

According to at least one example embodiment, a method of manufacturing a high electron mobility transistor includes forming a channel layer on a substrate; forming a channel supply layer on the channel layer; forming a depletion supply unit on the channel supply layer; forming a barrier layer on the depletion supply unit; and forming a gate electrode on the depletion supply unit and forming a source electrode and a drain electrode at both sides of the depletion supply unit.

The forming of the barrier layer may comprise forming the barrier layer using a material having a chemical formula of AlₓGa₁₋ₓN (0≦x≦1) or using SiN or Al₂O₃.

### BRIEF DESCRIPTION OF THE DRAWINGS

These and/or other examples will become apparent and more readily appreciated from the following description of at least one example embodiment, taken in conjunction with the accompanying drawings in which:

FIGS. 1A and 1B are cross-sectional views of a high electron mobility transistor (HEMT) according to at least one example embodiment;

FIGS. 2A to 2C are cross-sectional diagrams of a high electron mobility transistor according to at least one example embodiment;

FIG. 3 is a schematic energy band diagram of a gate region of a high electron mobility transistor according to at least one example embodiment;

FIG. 4 is a graph illustrating a gate current versus a gate voltage in a case where a barrier layer is installed in a gate region of a high electron mobility transistor according to an example embodiment; and

FIGS. 5A to 5D are diagrams illustrating a method of manufacturing a high electron mobility transistor according to an example embodiment.

### DETAILED DESCRIPTION

The present disclosure will now be described more fully with reference to the accompanying drawings, in which at least one example embodiment of the present disclosure are shown.

The present disclosure may, however, be embodied in many different forms and should not be construed as being limited to one or more of the example embodiments set forth herein; rather, at least one example embodiment is provided so that this disclosure will be thorough and complete, and will fully convey the concept of the present disclosure to those of ordinary skill in the art. It will also be understood that when a layer is referred to as being “on” another layer or substrate, it can be directly on the other layer or substrate, or intervening elements may also be present. In the drawings, the thicknesses of layers and regions are exaggerated for clarity. Like reference numerals in the drawings denote like elements, and thus their description will be omitted. The words “and/or” used in the present disclosure includes any and all combinations of one or more of the associated listed items. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “on,” “connected” or “coupled” to another element, it can be directly on, connected or coupled to the other element or intervening elements may be present. In contrast, when an element is referred to as being “directly on,” “directly connected” or “directly coupled” to another element, there are no intervening elements present. As used herein the term “and/or” includes any and all combinations of one or more of the associated listed items. Further, it will be understood that when a layer is referred to as being “under” another layer, it can be directly under or one or more intervening layers may also be present. In addition, it will also be understood that when a layer is referred to as being “between” two layers, it can be the only layer between the two layers, or one or more intervening layers may also be present.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

In the drawing figures, the dimensions of layers and regions may be exaggerated for clarity of illustration. Like reference numerals refer to like elements throughout. The same reference numbers indicate the same components throughout the specification.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein. As used herein, expressions such as “at least one of,” when preceding a list of elements, modify the entire list of elements and do not modify the individual elements of the list.

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain example embodiments of the present description.

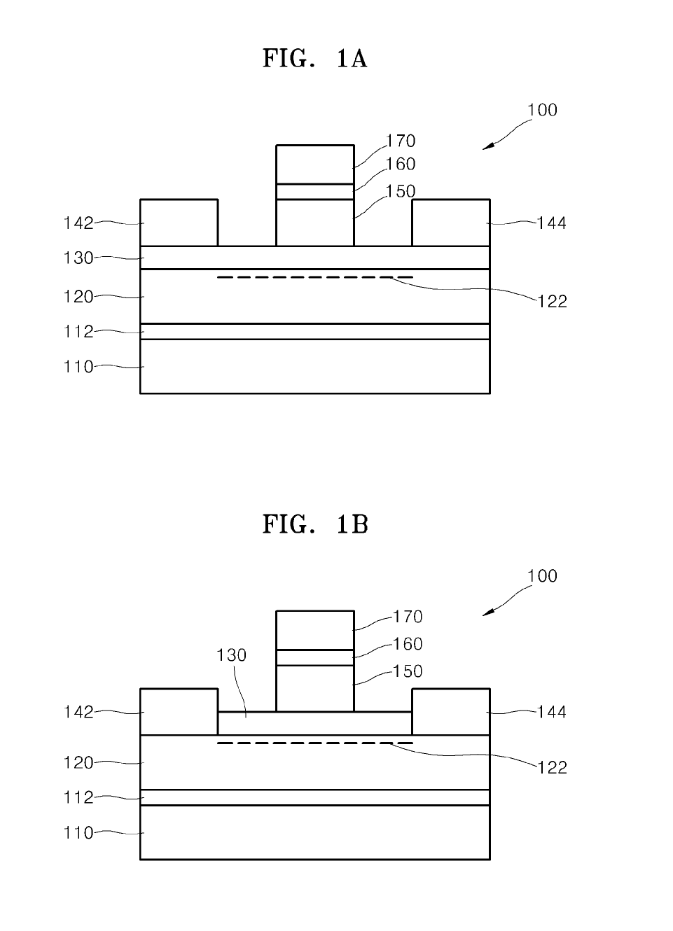

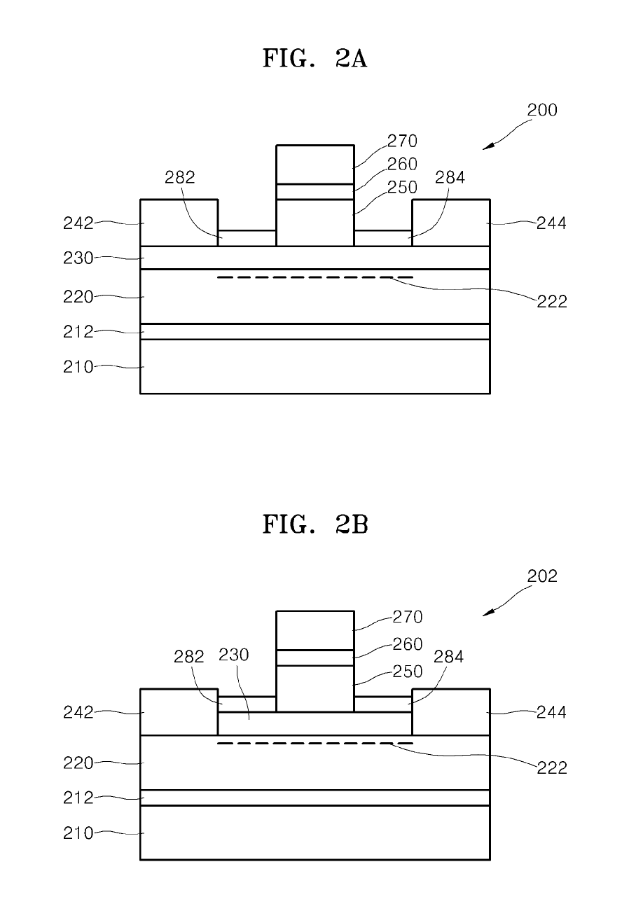

FIGS. 1A and 1B are cross-sectional views of a high electron mobility transistor (HEMT) 100 according to at least one example embodiment.

According to at least one example embodiment, referring to FIGS. 1A and 1B, the high electron mobility transistor 100 may include a substrate 110, and a buffer layer 112, a channel layer 120, and a channel supply layer 130 which are formed on the substrate 110. The high electron mobility transistor 100 may include a gate structure formed on a region of the channel supply layer 130. The gate structure may include a depletion forming layer 150 (alternatively referred as a depletion forming unit 150), a barrier layer 160, and a gate electrode 170. A source electrode 142 and a drain electrode 144 may be formed at both sides on the channel supply layer 130.

The substrate 110 may be formed to include, for example, silicon (Si), sapphire, silicon carbide (SiC), gallium nitride (GaN), or various combinations thereof. However, this is merely an example, and the substrate 110 may be formed of any of various other materials. The buffer layer 112 may be selectively formed to reduce differences in a lattice constant and a thermal expansion coefficient between the substrate 110 and the channel layer 120.

The buffer layer 112 may be formed of a nitride, and the nitride may include at least one of Al, Ga, In, and B. The buffer layer 112 may be formed to have a single-layered structure or a multi-layered structure. The buffer layer 112 may be AlₓIn_{y}Ga_{1-x-y}N (0≦x≦1, 0≦y≦1), and may include, for example, AlN, GaN, AlGaN, InGaN, AlInN, or AlGaInN. Alternatively, a seed layer for growing a semiconductor material layer may further be formed between the substrate 110 and the buffer layer 112. The substrate 110 and the buffer layer 112 may be removed after the manufacture of the high electron mobility transistor. That is, in the high electron mobility transistor, the substrate 110 and the buffer layer 112 may be selectively provided.

A channel layer 120 including a first semiconductor material may be formed on the substrate 110 and the buffer layer 112. The channel layer 120 may be a layer capable of forming a channel between the source electrode 142 and the drain electrode 144, and may be a semiconductor layer formed to have a single-layered structure or a multi-layered structure. The channel layer 120 may be formed of a semiconductor material having a chemical formula of AlₓIn_{y}Ga_{1-x-y}N (0≦x≦1, 0≦y≦1). For example, the channel layer 120 may include at least one of various materials including AlN, GaN, InN, InGaN, AlGaN, AlInN, and AlInGaN. However, the material of the channel layer 120 is not limited thereto, and any material may be used as the material of the channel layer 120 as along as it is a material capable of forming a two-dimensional electron gas (hereinafter, referred to as a 2DEG layer) 122 within the channel layer 120. The channel layer 120 may be an undoped layer, or may be a layer doped with desired (or alternatively predetermined) impurities when necessary.

In the channel layer 120, a 2DEG layer 122 may be formed by spontaneous polarization (Pₛp) and piezo-polarization (P_{PE}), due to external strain caused by lattice mismatch or the like. For example, the channel layer 120 may be formed to include GaN. In this case, the channel layer 120 may be an undoped GaN layer or a GaN layer doped with desired (or alternatively predetermined) impurities. A GaN-based semiconductor may have a high energy band gap and external properties such as a high thermal chemical stability and a high electron saturated velocity (e.g., 3×10⁷ cm/sec), and thus the GaN-based semiconductor may be used not only as an optical device but also as a high-frequency and high-power electron device. The example electronic device using a GaN-based semiconductor has various characteristics such as a high breakdown electric field (e.g., 3×10⁶ V/cm), a high peak current density, a stable high-temperature operation characteristic, and a high thermal conductivity. In a high electron mobility transistor using a GaN-based heterojunction structure, since band-discontinuity between the channel layer 120 and the channel supply layer 130 is large, electrons may be concentrated at a junction interface, and thus electron mobility may be increased. The channel layer 120 may have a thickness of about 30 nm to about 10 μm.

The channel supply layer 130 formed of a second semiconductor material may be provided on the channel layer 120. The channel supply layer 130 may include a material (semiconductor) having at least one different characteristic from among a polarization characteristic, an energy band gap, and a lattice constant, from the channel layer 120. The channel supply layer 130 may include a material having a larger polarizability and/or energy band gap than the channel layer 120. For example, the channel supply layer 130 may include at least one material selected from nitrides including at least one of Al, Ga, In, and B, and may be formed to have a single-layered structure or a multi-layered structure. For example, the channel supply layer 130 may include a semiconductor material having a chemical formula of AlₓIn_{y}Ga_{1-x-y}N (0≦x≦1, 0≦y≦1), and may have a single-layered structure or a multi-layered structure including at least one of various materials including AlGaN, AlInN, InGaN, AlN, AlInGaN, and the like. The channel supply layer 130 may be an undoped layer, or may be a layer doped with desired (or alternatively predetermined) impurities. The channel supply layer 130 may have a thickness of equal to or less than several tens of nm.

The channel supply layer 130 may generate the 2DEG 122 in the channel layer 120. Here, the 2DEG 122 may be formed below an interface between the channel layer 120 and the channel supply layer 130 within the channel layer 120. The 2DEG 122 formed in the channel layer 120 may be used as a current path between the source electrode 142 and the drain electrode 144, that is, a channel. The source electrode 142 and the drain electrode 144 may have various structural features in which the 2DEG 122 may be used as a channel. In FIG. 1A, the source electrode 142 and the drain electrode 144 are formed on the same plane of the channel supply layer 130 in which a gate structure is formed.

In FIG. 1B, according to at least one example embodiment, the source electrode 142 and the drain electrode 144 may be formed to come into contact with the channel layer 120. The present disclosure is not limited thereto, and the source electrode 142 and the drain electrode 144 may be formed to extend into the channel supply layer 130, or the source electrode 142 and the drain electrode 144 may be formed to extend into the channel layer 120. The source electrode 142 and the drain electrode 144 may be formed to have an ohmic contact structure with the channel layer 120 or with the channel supply layer 130.

At least one depletion forming layer 150 (alternatively referred to as a depletion forming unit 150) may be provided on the channel supply layer 130 between the source electrode 142 and the drain electrode 144. The depletion forming unit 150 may form a depletion region in the 2DEG 122. Conduction band energy and valence band energy in a portion of the channel supply layer 130 below the depletion forming unit 150 may be increased by the depletion forming unit 150, and the depletion region of the 2DEG 122 may be formed in a region of the channel layer 120 which corresponds to, or is below, the depletion forming unit 150. Thus, the 2DEG 122 may be disconnected or reduced in the region of the channel layer 120 which corresponds to, or is below, the depletion forming unit 150. In addition, the region of the channel layer 120 which corresponds to, or is below, the depletion forming unit 150 may have characteristics, for example, concentration of electrons, which are different from the same characteristics of other regions. The region in which the 2DEG 122 is disconnected may be referred to as a “disconnection region”, and the high electron mobility transistor according to an example embodiment may have a normally-off characteristic at the disconnection region. A normally-off structure refers to a structure in which the high electron mobility transistor is in an off state when a voltage is not applied to the gate electrode 170, that is, a normal state, and in which the high electron mobility transistor is in an on state when a voltage is applied to the gate electrode 170. The depletion forming unit is provided between the gate electrode 170 and the channel supply layer 130, and thus a normally-off structure may be formed.

The depletion forming unit 150 may include a p-type semiconductor material. That is, the depletion forming unit 150 may be a semiconductor layer doped with p-type impurities. The depletion forming unit 150 may include a Group III-V nitride semiconductor. For example, the depletion forming unit 150 may include at least one of GaN, AlGaN, InN, AlInN, InGaN, and AlInGaN, and may be doped with p-type impurities. For example, the depletion forming unit 150 may be a -GaN layer or a p-AlGaN layer. Conduction band energy and valence band energy in the portion of the channel supply layer 130 below the depletion forming unit 150 are increased, and thus the disconnection region of the 2DEG 122 may be formed. The depletion forming unit 150 may be formed to have a single-layered structure of a multi-layered structure between the source electrode 142 and the drain electrode 144. The depletion forming unit 150 may be formed to have a thickness equal to or less than several hundreds of nm, for example, a thickness of 30 nm to 250 nm.

The gate electrode 170 may be formed of a conductive material, or may be formed to include a metal, an alloy, a conductive metal oxide, or a conductive metal nitride. The gate electrode 170 may be formed to have the same width as the depletion forming unit 150. The source electrode 142 and the drain electrode 144 may be formed to include a metal, an alloy, a conductive metal oxide, a conductive metal nitride, or a Group IV semiconductor material. The source electrode 142, the drain electrode 144, and the gate electrode 170 may be formed to have a single-layered structure or a multi-layered structure.

The barrier layer 160 may be formed between the depletion forming unit 150 and the gate electrode 170. When the depletion forming unit 150 is provided between the channel supply layer 130 and the gate electrode 170 and when a gate bias is formed, a gate forward current may be increased. When the barrier layer 160 is formed, holes may be partially, substantially or entirely prevented from being injected in the depletion forming unit 150 from the gate electrode 170, and the barrier layer 160 may be referred to as a hole barrier layer. The barrier layer 160 may reduce the gate forward current without changing a threshold voltage and an on resistance. The barrier layer 160 may be formed of a same material as the material of the depletion forming unit 150, for example, a material having a band gap or a conduction band offset which is larger than that of p-GaN. The barrier layer 160 may be formed of a material having a chemical formula of AlₓGa₁₋ₓN (0≦x≦1), for example, AlN. In addition, the barrier layer 160 may be formed of an oxide (wide band gap oxide) having a wide band gap, and may include, for example, SiN and Al₂O₃. The barrier layer 160 may be formed to have a thickness of equal to or less than 100 nm, for example, a thickness of 0 nm to about 10 nm. However, this is merely an example, the present disclosure is not limited thereto.

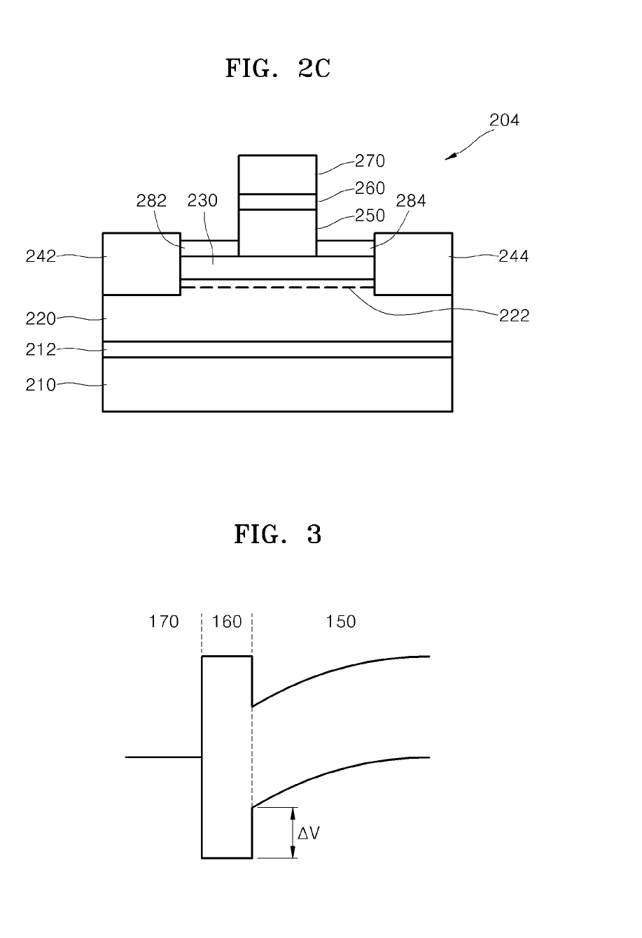

FIG. 3 is a schematic energy band diagram of a gate region of a high electron mobility transistor according to an example embodiment.

According to at least one example embodiment, referring to FIG. 3, during the driving of the high electron mobility transistor according to an example embodiment, holes may move toward the depletion forming unit 150 from the gate electrode 170. However, the formation of the barrier layer 160 may restrict the movement of the holes due to an energy barrier ΔV.

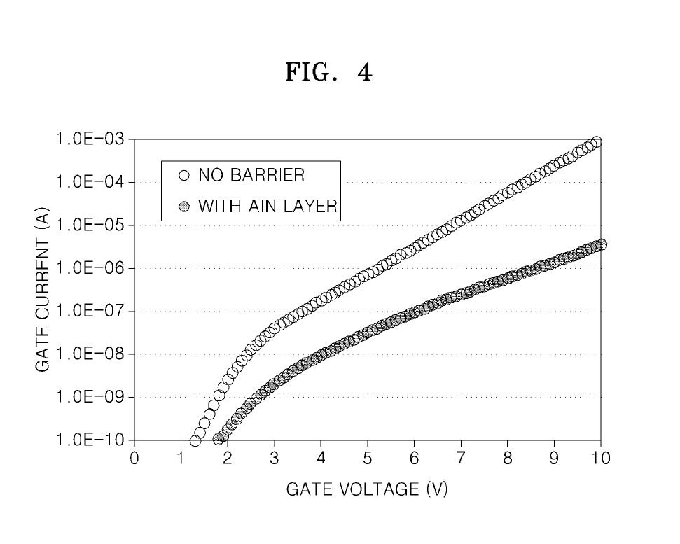

FIG. 4 is a graph illustrating a gate current A versus a gate voltage V in a case where a barrier layer is installed in a gate region of a high electron mobility transistor according to at least one example embodiment. At this time, the depletion forming unit 150 formed of p-GaN having a thickness of approximately 90 nm, the barrier layer 160 formed of AlN having a thickness of approximately 3 nm, and the gate electrode 170 formed to have a thickness of approximately 200 nm are used as samples.

Referring to FIG. 4, a gate current is reduced to a range between approximately 1/100 and 1/1000 when the AlN barrier layer 160 is formed between the depletion forming unit 150 and the gate electrode 170, as compared with a case where the barrier layer 160 is not formed (no barrier).

FIGS. 2A to 2C are cross-sectional diagrams of a high electron mobility transistor according to another example embodiment.

Referring to FIGS. 2A to 2C, the high electron mobility transistor according to at least one example embodiment may include a substrate 210 and a buffer layer 212, a channel layer 220, and a channel supply layer 230 which are formed on the substrate 210. The high electron mobility transistor may include a gate structure formed on a region of the channel supply layer 230. The gate structure may include a depletion forming unit 250, a barrier layer 260, and a gate electrode 270. A source electrode 242 and a drain electrode 244 may be formed at both sides of the gate electrode 270, and the gate structure may have various structures in which the source electrode 242 and the drain electrode 244 may be used as channels of a 2DEG 222. FIG. 2A illustrates a structure of a high electron mobility transistor 200 in which the source electrode 242 and the drain electrode 244 are formed on the same plane of the channel supply layer 230 in which a gate structure is formed. FIG. 2B illustrates a structure of a high electron mobility transistor 202 in which the source electrode 242 and the drain electrode 244 are formed to come into contact with the channel layer 220. FIG. 2C illustrates a structure of a high electron mobility transistor 204 in which the source electrode 242 and the drain electrode 244 extend into the channel layer 220. The source electrode 242 and the drain electrode 244 may be formed to have an ohmic contact structure with the channel layer 220 or with the channel supply layer 230.

As illustrated in FIGS. 2A to 2C, a bridge 282 and a bridge 284 may be formed on the channel supply layer 230 between the depletion forming unit 250 and the source 242 and/or on the channel supply layer 230 between the depletion forming unit 250 and the drain 244, respectively. The bridges 282 and 284 may be formed of the same material as the depletion forming unit 250. The bridges 282 and 284 may include a Group III-V nitride semiconductor. The bridges 282 and 284 may include at least one of GaN, AlGaN, InN, AlInN, InGaN, and AlInGaN, and may be doped with p-type impurities. For example, the bridges 282 and 284 may be formed to include a p-GaN layer or a p-AlGaN layer. The depletion forming unit 250 and the bridges 282 and 284 may be formed as one body, and may be formed to have the same height. In addition, the depletion forming unit 250 and the bridges 282 and 284 may be formed to have different heights, or the bridges 282 and 284 may be formed to have a lower height than the depletion forming unit 250. FIGS. 2A to 2C illustrate a continuous stacked structure in which the bridges 282 and 284 occupy a connecting space between the source electrode 242 and the depletion forming unit 250, and a space between the drain electrode 244 and the depletion forming unit 250. FIGS. 2A to 2C also illustrate a discontinuous stacked structure in which partial regions of the bridges 282 and 284 expose the channel supply layer 230 may be formed.

The materials for forming the layers described above with reference to FIGS. 1A and 1B may be adopted as materials for forming the layers illustrated in FIGS. 2A to 2C.

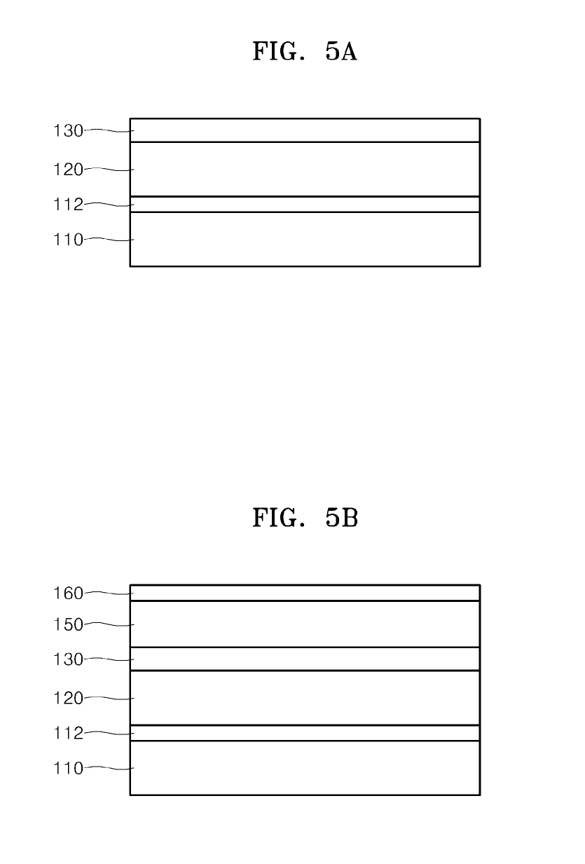

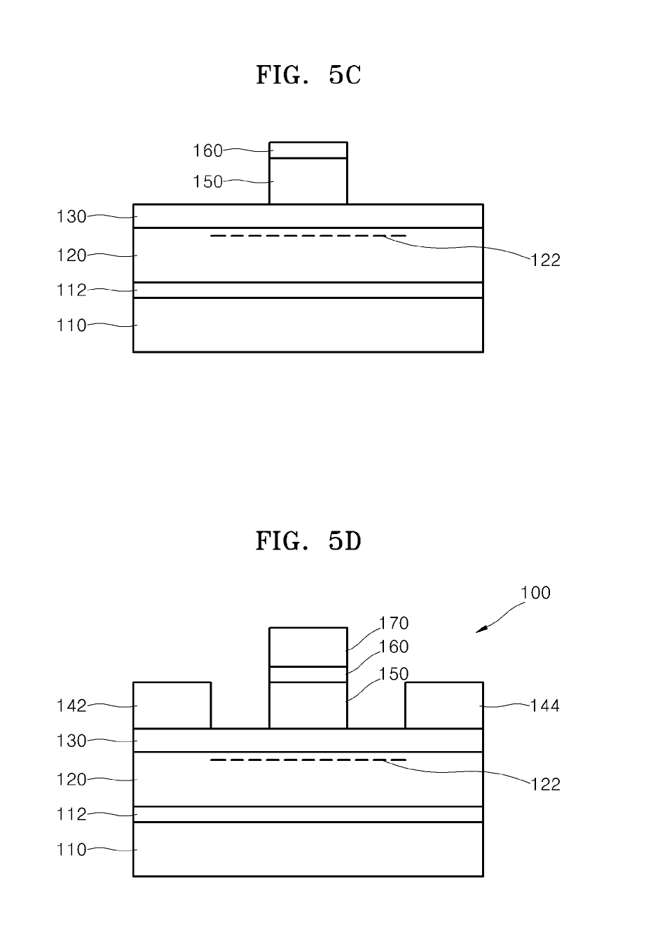

FIGS. 5A to 5D are diagrams illustrating a method of manufacturing a high electron mobility transistor according to at least one example embodiment. FIGS. 5A to 5D illustrate a method of manufacturing, for example, the high electron mobility transistor described above with reference to FIG. 1A. The high electron mobility transistor according to at least one example embodiment may be formed without limit by chemical vapor deposition (CVD), physical vapor deposition (PVD), or atomic layer deposition (ALD).

According to at least one example embodiment, referring to FIG. 5A, the buffer layer 112, the channel layer 120, and the channel supply layer 130 may be sequentially formed on the substrate 110. The substrate 110 may include Si, sapphire, SiC, GaN, or the like. The buffer layer 112 is formed to partially, substantially or entirely prevent the crystallinity of the channel layer 120 formed thereon from decreasing, and may be formed to have a single-layered structure or a multi-layered structure including at least one nitride including at least one of Al, Ga, In, and B. The buffer layer 112 may be formed to include at least one among various materials including AlN, GaN, InN, AlGaN, InGaN, AlInN, AlGaInN, and the like. A seed layer may further be formed between the substrate 110 and the buffer layer 112. The seed layer and the buffer layer 112 may be selectively formed. The channel layer 120 may include a semiconductor material, and may include at least one of various materials such as, for example, AlN, GaN, InN, AlInN, InGaN, AlGaInN, and AlGaN. The channel layer 120 may be an undoped layer, or may be formed by being doped with desired (or alternatively predetermined) impurities when desired. The channel supply layer 130 may be formed of a semiconductor material that may be different from the semiconductor material of the channel layer 120. In order to form the channel supply layer 130 on the channel layer 120, epitaxial growth may be performed. The channel supply layer 130 may be formed of a material having a different band gap energy from the band gap energy of the channel layer 120. For example, the channel supply layer 130 may be formed of a material having a larger band gap energy than the band gap energy of the channel layer 120. The channel supply layer 130 may be formed to have a single-layered structure or a multi-layered structure including at least one material selected from nitrides including at least one of Al, Ga, and In. For example, the channel supply layer 130 may be formed of a material including at least one of various materials including GaN, InN, AlGaN, AlInN, InGaN, AlN, AlInGaN, and the like. The channel supply layer 130 may be an undoped layer, or may be doped with impurities.

According to at least one example embodiment, referring to FIG. 5B, the depletion forming unit 150 may be formed on the channel supply layer 130. The depletion forming unit 150 may be formed of a p-type semiconductor, and may be formed to include at least one of, for example, AlN, GaN, AlGaN, InN, AlInN, InGaN, and AlInGaN. The depletion forming unit 150 may be formed of a p-type semiconductor layer doped with p-type impurities. For example, the depletion forming unit 150 may be a p-GaN layer or a p-AlGaN layer. A capping layer formed of a Group III-V nitride may further be formed between the channel supply layer 130 and the depletion forming unit 150. The barrier layer 160 may be formed on the depletion forming unit 150. The barrier layer 160 may be formed of a material having a larger band gap energy or a larger conduction band offset than the band gap energy of the conduction band offset of the depletion forming unit 150. The barrier layer 160 may be formed of a material having a chemical formula of AlₓGa₁₋ₓN (0≦x≦1), for example, AlN. The barrier layer 160 may be formed of a wide band gap oxide, for example, SiN or Al₂O₃. The barrier layer 160 may be formed to have a thickness equal to or less than about 100 nm, for example, a thickness of about 0 nm to about 10 nm. The barrier layer 160 may be formed by an in-situ or ex-situ process. For example, the depletion forming unit 150 may be formed by a metal oxide chemical vapor deposition (MOCVD) process, and then the barrier layer 160 may be formed on the depletion forming unit 150 during the same process. In addition, the depletion forming unit 150 may be formed by a MOCVD process, and then the barrier layer 160 may be formed by an atomic layer deposition (ALD) process.

According to at least one example embodiment, referring to FIGS. 5C and 5D, the depletion forming unit 150 and the barrier layer 160 are partially etched. Then, in order to form electrodes, the gate electrode 170, the source electrode 142, and the drain electrode 144 may be formed of a metal, an alloy, a conductive metal oxide, a conductive metal nitride, or a Group IV semiconductor material. The gate electrode 170, the source electrode 142, and the drain electrode 144 may be formed contemporaneously or separately. When the gate electrode 170, the source electrode 142, and the drain electrode 144 are formed, a mask or an etching process may be used without limit depending on the type or nature of the electrode materials.

The high electron mobility transistor described above may be used as, for example, a power device. However, the high electron mobility transistor according to the present disclosure may be applied not only to a power device but also to various other fields. That is, the high electron mobility transistor according to at least one example embodiment may be used not only for a power device but also for various other uses such as a radio frequency (RF) switching device.

In addition, another layer may be interposed between the layers of the high electron mobility transistor according to at least one example embodiment.

A depletion supply unit and a barrier layer may be provided between a channel supply layer and a gate electrode, and thus a high electron mobility transistor having a normally-off characteristic may be realized.

In addition, holes may be partially, substantially or entirely prevented from moving in a direction toward the depletion supply unit from the gate electrode.

A gate forward current may be reduced without changing a threshold voltage and an on resistance of the semiconductor device.

It should be understood that one or more exemplary embodiments described therein should be considered in a descriptive sense only and not for purposes of limitation. Descriptions of features within each example embodiment should typically be considered as available for other similar features in one or more other embodiments.

While one or more embodiments of at least one example embodiment have been described with reference to the figures, it will be understood by those of ordinary skill in the art that various changes in form and details may be made therein without departing from the spirit and scope of at least one example embodiment as defined by the following claims.

What is claimed is:

1. A high electron mobility transistor comprising:
a channel layer on a substrate;
a channel supply layer on the channel layer;
a source electrode and a drain electrode on at least one of the channel layer and the channel supply layer;
a gate structure on the channel supply layer between the source electrode and the drain electrode,
wherein the gate structure comprises a depletion forming layer on the channel supply layer, a barrier layer on the depletion forming layer, and a gate electrode on the barrier layer.

2. The high electron mobility transistor of claim 1, wherein the barrier layer comprises a material having a larger band gap energy or a larger conduction band offset than the band gap energy or the conduction band offset of a material of the depletion forming layer.

3. The high electron mobility transistor of claim 2, wherein the barrier layer comprises a material having a chemical formula of AlₓGa₁₋ₓN (0≦x≦1).

4. The high electron mobility transistor of claim 2, wherein the barrier layer comprises AlN.

5. The high electron mobility transistor of claim 2, wherein the barrier layer comprises an oxide.

6. The high electron mobility transistor of claim 2, wherein the barrier layer comprises at least one of SiN and Al₂O₃.

7. The high electron mobility transistor of claim 2, wherein the barrier layer has a thickness that is equal to or less than 100 nm.

8. The high electron mobility transistor of claim 1, wherein the depletion forming layer comprises a Group III-V nitride semiconductor material.

9. The high electron mobility transistor of claim 8, wherein the depletion forming layer comprises at least one of GaN, AlGaN, InN, AlInN, InGaN, and AlInGaN.

10. The high electron mobility transistor of claim 8, wherein the depletion forming layer comprises a p-type semiconductor material.

11. The high electron mobility transistor of claim 8, wherein the depletion forming layer has a thickness of about 30 nm to about 200 nm.

12. The high electron mobility transistor of claim 1, wherein the source electrode and the drain electrode are on the channel supply layer.

13. The high electron mobility transistor of claim 1, wherein the source electrode and the drain electrode are on a surface of the channel layer.

14. The high electron mobility transistor of claim 1, wherein the source electrode and the drain electrode extend into at least a portion of the channel layer.

15. The high electron mobility transistor of claim 1, further comprising:
a bridge at least one of between the source electrode and the depletion forming layer and between the drain electrode and the depletion forming layer.

16. The high electron mobility transistor of claim 15, wherein the bridge comprises a Group III-V nitride semiconductor.

17. A method of manufacturing a high electron mobility transistor, the method comprising:
forming a channel layer on a substrate;
forming a channel supply layer on the channel layer;
forming a depletion forming layer on the channel supply layer;
forming a barrier layer on the depletion forming layer;
forming a gate electrode on the barrier layer; and
forming a source electrode and a drain electrode at respective sides of the depletion forming layer.

18. The method of claim 17, wherein the forming a barrier layer forms the barrier layer using a material comprising at least one of AlₓGa₁₋ₓN (0≦x≦1), SiN and Al₂O₃.
